(19) United States
(12) Patent Application Publication
(10) Pub. No.: US 2026/0075755 A1
(43) Pub. Date: Mar. 12, 2026

(54) CONNECTION DEVICE

(71) Applicant: Molex, LLC, Lisle, IL (US)

(72) Inventors: Wei-Che Sun, New Taipei City (TW); Che-Yuan Yang, New Taipei City (TW); Wen-Chih Chen, New Taipei City (TW)

(21) Appl. No.: 19/321,304

(22) Filed: Sep. 8, 2025

(30) Foreign Application Priority Data
Sep. 12, 2024 (CN) 2024112763642

(51) Int. Cl. H05K 7/20; H01R 12/70; H01R 13/512; H01R 13/518

(52) U.S. Cl. CPC H05K 7/20254; H01R 12/7082; H01R 13/512; H01R 13/518

(57) ABSTRACT

A connection device includes a connector assembly, a liquid cooling plate and a framework. The connector assembly includes a metal shell. The metal shell has two side walls. Each side wall has a protruding portion and a side retaining portion. An interior of the liquid cooling plate allows a cooling liquid to communicate therein. The framework includes two side frames which are respectively fixed to two sides of the liquid cooling plate. Each side frame has a side latching member and a first position-limiting member. The side latching members are capable of being respectively releasable to latch to the side retaining portions. Each first position-limiting member has a guiding groove. The guiding grooves are capable of respectively allowing the protruding portions to slide therein. The first position-limiting members let the protruding portions respectively slide into the guiding grooves to make the side latching members respectively latch to the side retaining portions, so that the liquid cooling plate and the connector assembly are engaged with each other.

### TECHNICAL FIELD

The present disclosure relates to a connection device, and particularly relates to a connection device having a framework.

### BACKGROUND

In a process that a general connector assembly is electrically connected with a pluggable assembly and performs an operation, overheat problem will generally occurs, so, the existing connector assembly will be configured with a liquid cooling plate to attain an effect of lowering temperature. A common configuration manner is that the liquid cooling plate is assembled on a circuit board, which is provided with a connector assembly, by means of a framework, to make liquid cooling plate be capable of thermally engaging with a pluggable assembly which inserts into the connector assembly, however, the framework and the circuit board are generally screwed by screws, which results in that the circuit board must reserve holes for the screws and cannot be miniaturized. Moreover, in a process that the framework is assembled with the connector assembly or the circuit board, the framework and the connector assembly or the circuit board must be aligned with each other and are locked by screws, which is time-consuming and labor consuming.

### SUMMARY

Therefore, an object of the present disclosure is to provide a connection device which can solve at least one above problem.

Accordingly, a connection device of the present disclosure comprises a connector assembly, a liquid cooling plate and a framework. The connector assembly comprises a metal shell. The metal shell has two side walls. Each side wall has a protruding portion and a side retaining portion. An interior of the liquid cooling plate allows a cooling liquid to communicate therein. The framework comprises two side frames which are respectively fixed to two sides of the liquid cooling plate. Each side frame has a side latching member and a first position-limiting member. The side latching members are capable of being respectively releasable to latch to the side retaining portions. Each first position-limiting member has a guiding groove. The guiding grooves are capable of respectively allowing the protruding portions to slide therein. The first position-limiting members let the protruding portions respectively slide into the guiding grooves to make the side latching members respectively latch to the side retaining portions, so that the liquid cooling plate and the connector assembly are engaged with each other, and the liquid cooling plate is limited to displacing relative to the connector assembly.

In some embodiments, the two side frames and the liquid cooling plate are screwed by using screws.

In some embodiments, the framework further comprises a front frame whose left side and right side are respectively connected to front sides of the side frames, and a rear frame whose left side and right side are respectively connected to rear sides of the side frames, the front frame, the rear frame and the two side frames together surround a periphery of the liquid cooling plate.

In some embodiments, an opening of the guiding groove is toward the front; the framework further comprises a rear frame whose left side and right side are respectively connected to rear sides of the side frames, the metal shell further has a rear wall which is positioned to a rear side of the metal shell, the rear wall has a rear retaining portion which protrudes rearwardly; the rear frame has a rear positioning hole which penetrates front and rear, the rear positioning hole is capable of allowing the rear retaining portion to pass therein from the front to the rear.

In some embodiments, an opening of the guiding groove is toward the front; each side wall has a side wall main body and the side retaining portion which is provided to the side wall main body, each side retaining portion has a first guiding surface which extends outwardly and rearwardly from an outer surface of the side wall main body; the side latching members are capable of being elastically deformed when the side latching members are respectively subjected to forces, each side latching member has a first latching hole which penetrates a left surface and a right surface of the side latching member and is capable of allowing the side retaining portion to pass therein; in a process that the first position-limiting members let the protruding portions respectively slide into the guiding grooves, the side latching members are respectively subjected to forces to be elastically deformed respectively along the first guiding surfaces toward directions respectively away from outer surfaces of the side walls, to make the first latching holes be capable of respectively being passed therein by the side retaining portions, so that the liquid cooling plate and the connector assembly are engaged with each other.

A connector assembly of the present disclosure comprises a metal shell, a liquid cooling plate and a framework. The metal shell has two side walls, each side wall has a side retaining portion and a lower stopping portion. An interior of a liquid cooling plate allows a cooling liquid to communicate therein. The framework comprises two side frames which are respectively fixed to two sides of the liquid cooling plate, each side frame has a side latching member and a second position-limiting member, the side latching members are capable of being respectively releasable to latch to the side retaining portions. By that the side latching members respectively latch to the side retaining portions and the second position-limiting members are stopped respectively by the lower stopping portions, the liquid cooling plate and the connector assembly are engaged with each other.

In some embodiments, each side wall has the two side retaining portions which are provided front and rear; each side frame has the two side latching members which are provided front and rear.

In some embodiments, each side retaining portion has a first guiding surface which extends outwardly and downwardly, each side latching member is capable of being elastically deformed when the side latching member is subjected to a force, and has a first latching hole which is capable of allowing the side retaining portion to pass therein, the side latching members are respectively subjected to forces to be elastically deformed respectively along the first guiding surfaces, to make the first latching holes be capable of being respectively passed therein by the side retaining portions, so that the liquid cooling plate and the connector assembly are engaged with each other.

In some embodiments, each side latching member further has a side latching body and a first latching guide portion which extends downwardly and outwardly from a bottom of the side latching body, the side latching body is formed with the first latching hole; when the framework brings the liquid cooling plate to approach the connector assembly from up to down, the first latching guide portions are pushed respectively by the side retaining portions to bring the side latching bodies to be elastically deformed outwardly.

In some embodiments, when the side latching members respectively latch to the side retaining portions, the second position-limiting members are respectively abutted by the lower stopping portions to be limited to moving downwardly, and the side latching members are respectively abutted by the side retaining portions to be limited to moving upwardly.

In some embodiments, each side wall further has two side stopping portions which are respectively provided between a front side and a rear side of the lower stopping portion and the adjacent side retaining portions; when the framework brings the liquid cooling plate to approach the connector assembly from up to down, the side latching members are respectively limited by the side stopping portions and cannot move front and rear.

In some embodiments, the metal shell further has a rear wall which is positioned to a rear side of the metal shell, the rear wall has a rear wall main body and a rear retaining portion which is provided to the rear wall main body, the rear retaining portion has a second guiding surface which extends outwardly and downwardly from an outer surface of the rear wall main body; the framework further comprises a rear frame which is fixed to a rear side of the liquid cooling plate, the rear frame has a rear latching member, the rear latching member extends downwardly and is capable of being elastically deformed when the rear latching member is subjected to a force, the rear latching member has a second latching hole which is capable of allowing the rear retaining portion to pass therein; when the rear latching member is subjected to a force to be elastically deformed along the second guiding surface, the second latching hole is capable of being passed therein by the rear retaining portion.

In some embodiments, the rear latching member further has a rear latching body and a second latching guide portion which extends downwardly and outwardly from a bottom of the rear latching body, the rear latching body is formed with the second latching hole; when the framework brings the liquid cooling plate to approach the connector assembly from up to down, the second latching guide portion is pushed by the rear retaining portion to bring the rear latching body to be elastically deformed outwardly.

In some embodiments, the rear frame further has an oppressing member, the oppressing member has a plate portion which extends downwardly and is capable of being elastically deformed, and a protruding bar which extends from the plate portion toward a direction close to the rear wall; when the framework brings the liquid cooling plate to approach the connector assembly from up to down, the protruding bar is subjected a force applied from the rear wall to bring the plate portion to be elastically deformed toward a direction away from the rear wall, and a first elastic restoring force which is toward the front is generated, the first elastic restoring force lets the framework forwardly and tightly lean against the connector assembly.

In some embodiments, each side frame further has a guiding member, the guiding member has an elastic piece portion which extends downwardly, a pressing portion which downwardly extends from the elastic piece portion close to the side wall, and a guiding portion which extends downwardly and outwardly from a bottom of the pressing portion, the elastic piece portion is capable of being elastically deformed when the elastic piece portion is subjected to a force; when the framework brings the liquid cooling plate to approach the connector assembly from up to down, the guiding portions are respectively pushed by top edges of the side walls to respectively bring the elastic piece portions to be elastically deformed toward directions respectively away from the side walls, and second elastic restoring forces are generated, the second elastic restoring forces let the pressing portions respectively press against the side walls.

In some embodiments, each side latching member is capable of being elastically deformed when the side latching member is subjected to a force, and has a first latching hole which is capable of allowing the side retaining portion to pass therein, the second position-limiting member has an extending portion which extends downwardly, and an abutting portion which extends inwardly from a bottom of the extending portion, when the side latching members respectively latch to the side retaining portions, the abutting portions of the second position-limiting members are respectively abutted by the lower stopping portions to be limited to moving downwardly, and bottom edges of inner walls of the first latching holes are respectively abutted by bottom surfaces of the side retaining portions to be limited to moving upwardly.

A connection device of the present disclosure comprises a connector assembly, a liquid cooling plate and a framework. The connector assembly comprises a metal shell, the metal shell has two side walls, each side wall has a side retaining portion. An interior of a liquid cooling plate allows a cooling liquid to communicate therein. The framework comprises two side frames which are respectively fixed to two sides of the liquid cooling plate, and a rear frame whose left side and right side are respectively connected to the side frames and are fixed to a rear side of the liquid cooling plate, the side frames and the rear frame together define a receiving space, the receiving space allows the liquid cooling plate to placed therein, each side frame has a side latching member, the side latching members are capable of being releasable to respectively latch to the side retaining portions, so that the liquid cooling plate and the connector assembly are engaged with each other, and the liquid cooling plate is limited to displacing relative to the connector assembly.

In some embodiments, the framework further comprises a front frame whose left side and right side are respectively connected to the side frames, the front frame and the rear frame respectively fixed to a front side and the rear side of the liquid cooling plate, the front frame, the rear frame and the two side frames together surround a periphery of the liquid cooling plate.

A beneficial effect of the present disclosure lies in that: by that the side latching members respectively latch with the side retaining portions, the liquid cooling plate can be directly assembled to the connector assembly by means of the framework, the liquid cooling plate and the connector assembly are compactly engage with each other, which does not increase an area occupying the circuit board, and further can save a step of locking the screws, an effect that assembling convenience is promoted is attained. Moreover, by a design of the guiding grooves or the first guiding surfaces, an assembling direction of the framework can be guided, an effect that assembling convenience is promoted can be similarly attained, on the other hand, by that the receiving space receives the liquid cooling plate, and the framework is at least fixed to three sides of the liquid cooling plate, the liquid cooling plate can be firmly assembled to the framework, durability is promoted.

### BRIEF DESCRIPTION OF THE DRAWINGS

Other features and effects of the present disclosure will be apparent from embodiments with reference to the drawings, in which:

FIG. 1 is a perspective view illustrating an implementing manner of a first embodiment of a connection device of the present disclosure;

FIG. 2 is a perspective exploded view of the first embodiment with a circuit board of the first embodiment removed;

FIG. 3 is a perspective view of FIG. 1 viewed from a different angle;

FIG. 4 is a perspective exploded view of FIG. 3 viewed from the corresponding angle with the circuit board removed;

FIG. 5 is a partially enlarged view of FIG. 3 with the circuit board removed;

FIG. 6 is a partially exploded view of FIG. 3 viewed from the corresponding angle and illustrating an assembling manner of a framework together with a liquid cooling plate of the first embodiment assembled to a connector assembly of the first embodiment;

FIG. 7 is a perspective view illustrating an implementing manner of a second embodiment of the connection device of the present disclosure;

FIG. 8 is a perspective exploded view of the second embodiment with a circuit board of the second embodiment removed;

FIG. 9 is a perspective view of FIG. 7 viewed from a different angle;

FIG. 10 is a perspective exploded view of FIG. 9 viewed from the corresponding angle with the circuit board removed;

FIG. 11 is a partially enlarged view of FIG. 9;

FIG. 12 is a cross-sectional view taken along a line XII-XII of FIG. 11;

FIG. 13 is a cross-sectional view taken along a line XIII-XIII of FIG. 11; and

FIG. 14 is a partially exploded view of FIG. 9 viewed from the corresponding angle and illustrating an assembling manner a framework together with a liquid cooling plate of the second embodiment assembled to a connector assembly of the second embodiment.

### DETAILED DESCRIPTION

Before the present disclosure is described in detail, it is noted that the similar elements are indicated by the same reference numerals in the following described content.

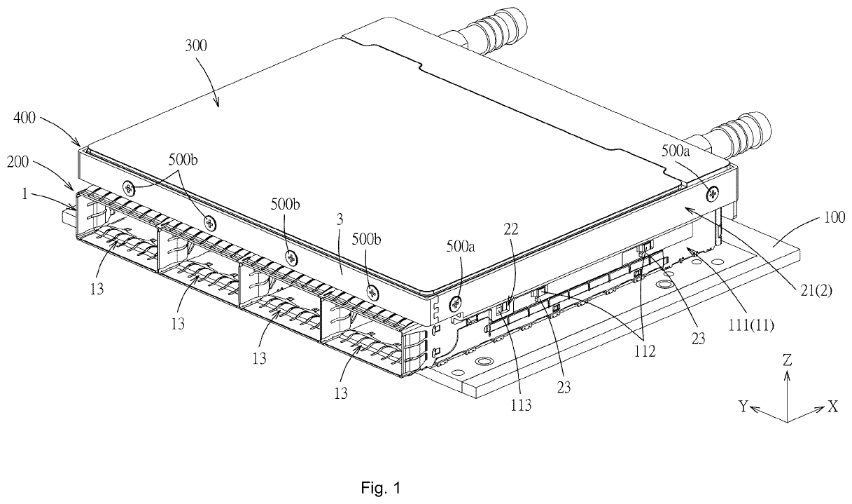

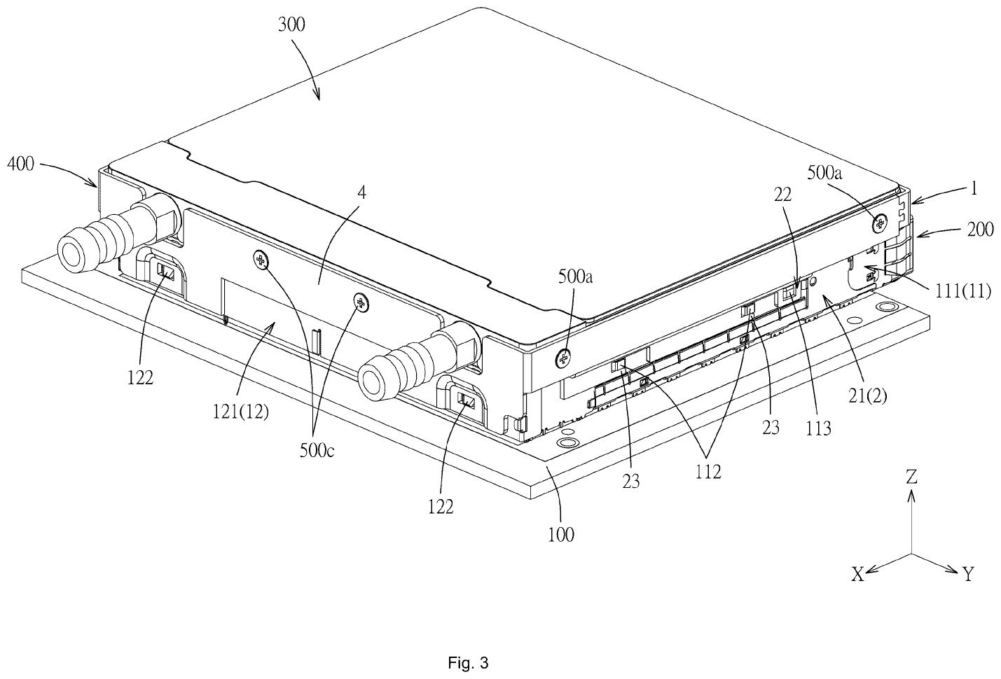

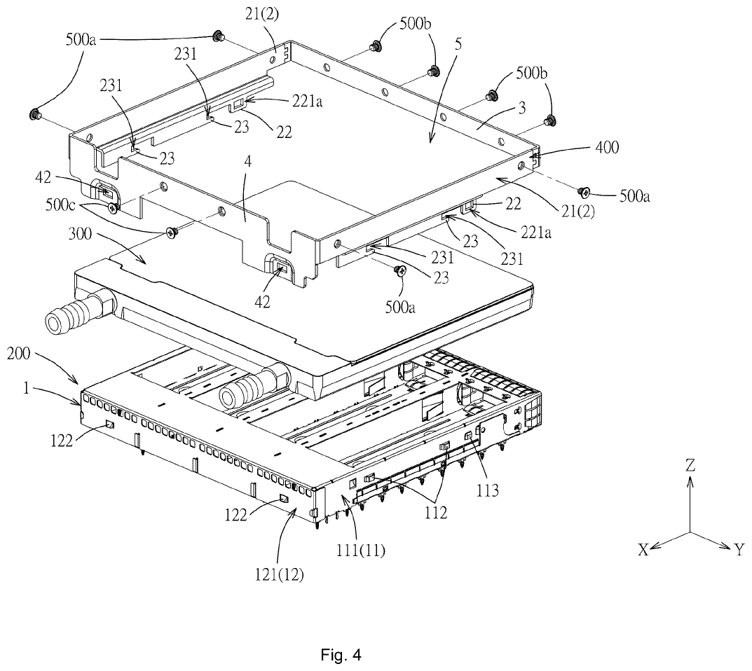

Referring to FIG. 1 to FIG. 6, a first embodiment of a connection device of the present disclosure is illustrated. The connection device is adapted to allow a plurality of pluggable assemblies (not shown) to be electrically connected therewith, and includes a circuit board 100, a connector assembly 200, a liquid cooling plate 300, a framework 400 and a plurality of screws. For sake of convenient description below, directional terms of the connection device are defined by the use circumstance of the connection device, that is, in FIG. 1, an arrow of a front-rear direction X points to a rear side of the connection device, an opposite direction is a front side; in FIG. 1, an arrow of a left-right direction Y points to a left side of the connection device, an opposite direction is right side; in FIG. 1, an arrow of an up-down direction Z points to an upper side of the connection device, an opposite direction is a lower side. Moreover, for sake of simplifying the described content, the plurality of screws take the screws 500a, 500b, 500c as example according to different coupling relationships.

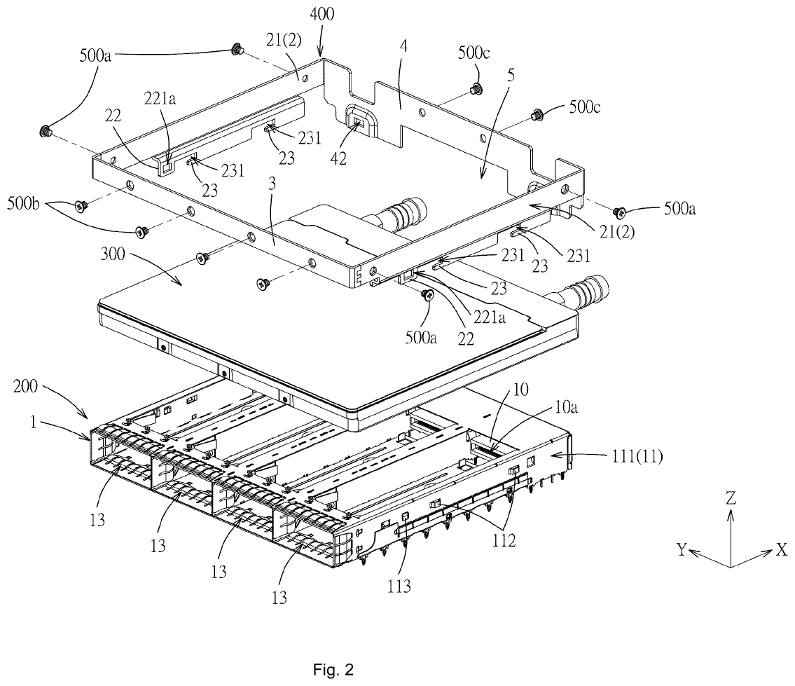

Referring to FIG. 1 and FIG. 2, the circuit board 100 is provided with a circuit pattern (not shown), and allows the connector assembly 200 to be provided thereon. The connector assembly 200 includes a metal shell 1 whose interior provides a plurality of inserting passageways 13, and a plurality of electrical connectors 10 (see FIG. 2) which are respectively provided to rear ends of the plurality of inserting passageways 13. Each electrical connector 10 has a mating slot 10a which allows the pluggable assembly to mate and electrical connect therewith. An opening of each inserting passageway 13 is toward the front and each inserting passageway 13 extends along the front-rear direction X, so as to allow the pluggable assembly to insert therein from the front to the rear. In the present embodiment, the number of the inserting passageway 13 takes four as example, and the inserting passageways 13 are arranged along the left-right direction Y, but the number of the inserting passageway 13 also may be one, two, three or five or more, and is not limited to the specific number.

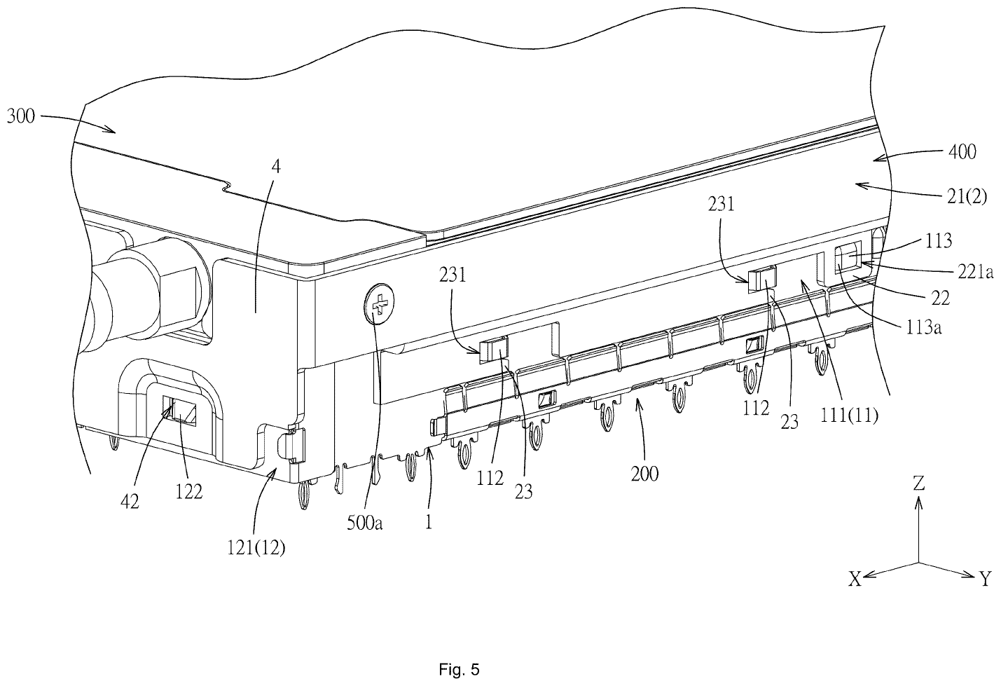

Referring to FIG. 1 to FIG. 5, for example, the metal shell 1 is formed by processing, such as stamping and bending, a metal sheet via a mold, and may be used to electromagnetically shield. The metal shell 1 is in form of cuboid, but is not limited thereto, and has two side walls 11 which are respectively positioned to a left side and a right side of the metal shell 1, and a rear wall 12 whose left side and right side are respectively connected to rear sides of the two side walls 11. Each side wall 11 has a side wall main body 111, a plurality of protruding portions 112 which protrude outwardly in the left-right direction Y from an outer surface of the side wall main body 111 (that is, in a direction away from the side wall main body 111), and a side retaining portion 113. Each side retaining portion 113 has a first guiding surface 113a (see FIG. 5) which extends outwardly and rearwardly from the outer surface of the side wall main body 111. In the present embodiment, the number of the protruding portion 112 takes two as example, but depending on use situation, the number of the protruding portion 112 also may be only one or three or more. Moreover, the side retaining portion 113 and the two protruding portions 112 are arranged along the front-rear direction X, but the arrangement manner of the side retaining portion 113 and the two protruding portions 112 also may be changed depending on the use situation.

The liquid cooling plate 300 is positioned above the connector assembly 200 and an interior of the liquid cooling plate 300 allows a cooling liquid to communicate therein, and the liquid cooling plate 300 is used to thermally engage with the pluggable assembly which inserts into the inserting passageway 13, so as to lower a temperature of the pluggable assembly. The framework 400 includes two side frames 2 which are provided to be spaced apart from each other left and right, a front frame 3 whose left side and right side are respectively connected to front sides of the two side frames 2, and a rear frame 4 whose left side and right side are respectively connected to rear sides of the two side frames 2. The front frame 3, the rear frame 4 and the two side frames 2 together define a receiving space 5, the receiving space 5 allows the liquid cooling plate 300 to be placed therein, so that the front frame 3, the rear frame 4 and the two side frames 2 together surround a periphery of the liquid cooling plate. Preferably, the two side frames 2 are respectively screwed and fixed to a left side and a right side of the liquid cooling plate 300 by using the screws 500a, the front frame 3 is screwed and fixed to a front side of the liquid cooling plate 300 by using the screws 500b, and the rear frame 4 is screwed and fixed to a rear side of the liquid cooling plate 300 by using the screws 500c, as such, the framework 400 and the liquid cooling plate 300 can be firmly engaged with each other.

Each side frame 2 has a side frame main body 21, a side latching member 22 which extends downwardly from a bottom edge of the side frame main body 21, and a plurality of first position-limiting members 23. The side latching members 22 are capable of being elastically deformed when the side latching members 22 are respectively subjected to forces. Each side latching member 22 has a first latching hole 221a which penetrates a left surface and a right surface of the side latching member 22 and is capable of allowing the side retaining portion 113 to pass therein. When the side retaining portions 113 respectively pass into the first latching holes 221a, the side latching members 22 are limited to moving up, down, front, and rear by the side retaining portions 113 respectively, that is, the side latching members 22 respectively latch to the side retaining portions 113, so that the liquid cooling plate 300 is assembled to the connector assembly 200 by means of the framework 400, so as to be engage with and stack up and down with the connector assembly 200, and the liquid cooling plate 300 is limited to displacing relative to the connector assembly 200 by the framework 400. When the side latching members 22 are subjected to forces respectively and are elastically deformed respectively toward directions which are respectively away from the side wall main bodies 111, the side retaining portions 113 respectively withdraw from the first latching holes 221a, that is, latching of the side latching members 22 respectively to the side retaining portions 113 is released.

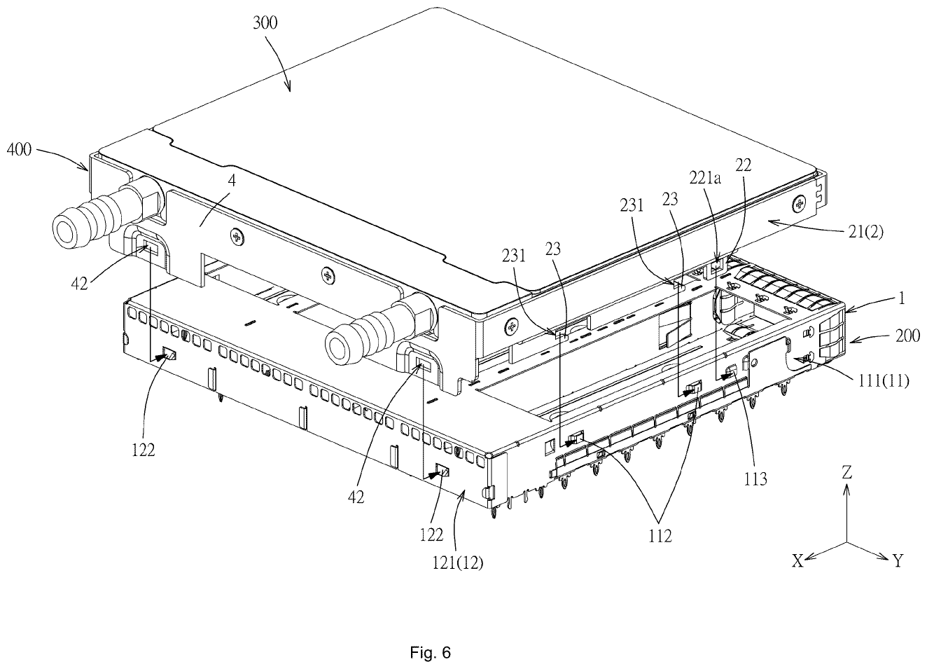

Referring to FIG. 5 and FIG. 6, each first position-limiting member 23 has a guiding groove 231 whose opening is toward the first guiding surface 113a (that is, toward the front). The guiding grooves 231 extend along the front-rear direction X and respectively allow the protruding portions 112 to be capable of relatively moving in the front-rear direction X and slide therein, so as to limit the framework 400 to moving up and down in a process that the protruding portions 112 slide relative to the guiding grooves 231 respectively. Specifically, in a process that the liquid cooling plate 300 is assembled to the connector assembly 200 by means of the framework 400, the framework 400 will be firstly operated to move downwardly as shown by solid arrows in FIG. 6 so that the openings of the guiding grooves 231 are respectively aligned with the protruding portions 112, next, the framework 400 is continuously operated to move forwardly as shown by solid arrows in FIG. 6 (opposite to a direction which is pointed by the arrow of the front-rear direction X in FIG. 6), so that the first position-limiting members 23 respectively slide relative to the protruding portions 112 to let the protruding portions 112 respectively slide into the guiding grooves 231, finally, when the protruding portions 112 respectively pass into tips of the guiding grooves 231, the side latching members 22 are respectively abutted by the side retaining portions 113 and are respectively applied to forces by the side retaining portions 113, to be elastically deformed respectively along the first guiding surfaces 113a toward directions which are respectively away from the outer surfaces of the side wall main bodies 111, so that the first latching holes 221a are capable of being respectively passed therein by the side retaining portions 113, and the liquid cooling plate 300 and the connector assembly 200 are engaged with each other, as such, the liquid cooling plate 300 is assembled on the connector assembly 200 by means of the framework 400 in a process without a tool and screws being locked, thereby attaining an effect that assembling convenience is promoted.

Preferably, the rear wall 12 has a rear wall main body 121 and two rear retaining portions 122 which protrude outwardly from an outer surface of the rear wall main body 121 in the front-rear direction X (that is, toward the rear) and are side by side left and right. The rear frame 4 has two rear positioning holes 42 which are provided left and right and penetrate front and rear. The rear positioning holes 42 are capable of respectively allowing the rear retaining portions 122 to pass therein from the front to the rear, so that the rear positioning holes 42 are respectively limited to moving up, down, left and right by the rear retaining portions 122 respectively, as such, as shown in FIG. 6, when the framework 400 is operated to move forwardly, the rear retaining portions 122 will respectively pass into the rear positioning holes 42 to attain an effect that the framework 400 is limited to moving, thereby promoting assembling stability.

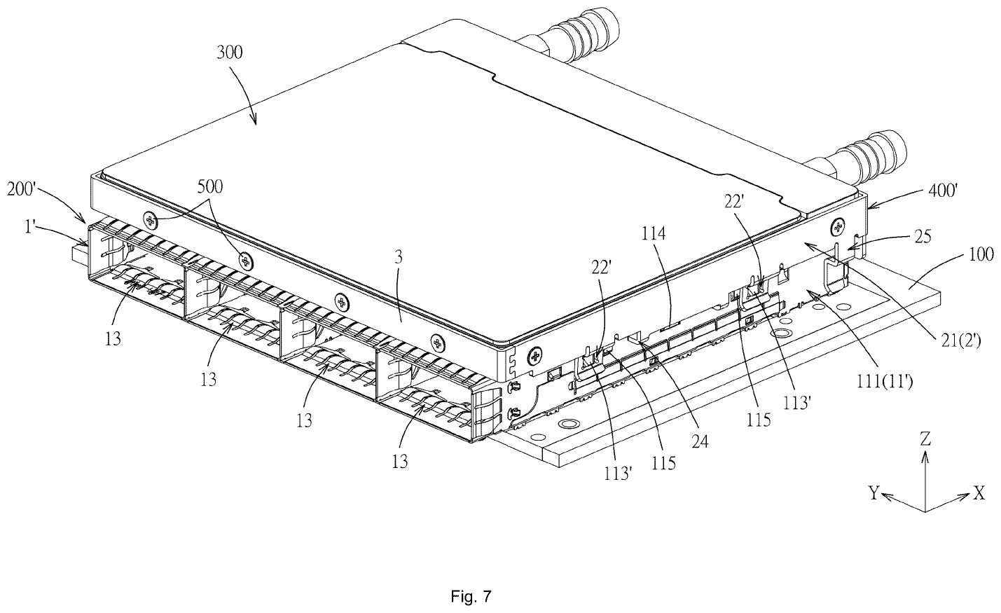

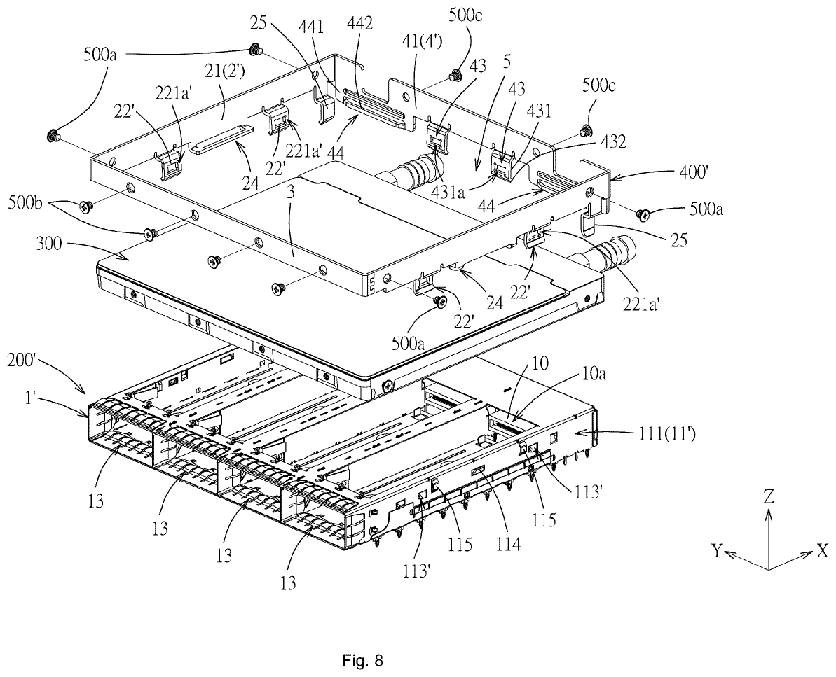

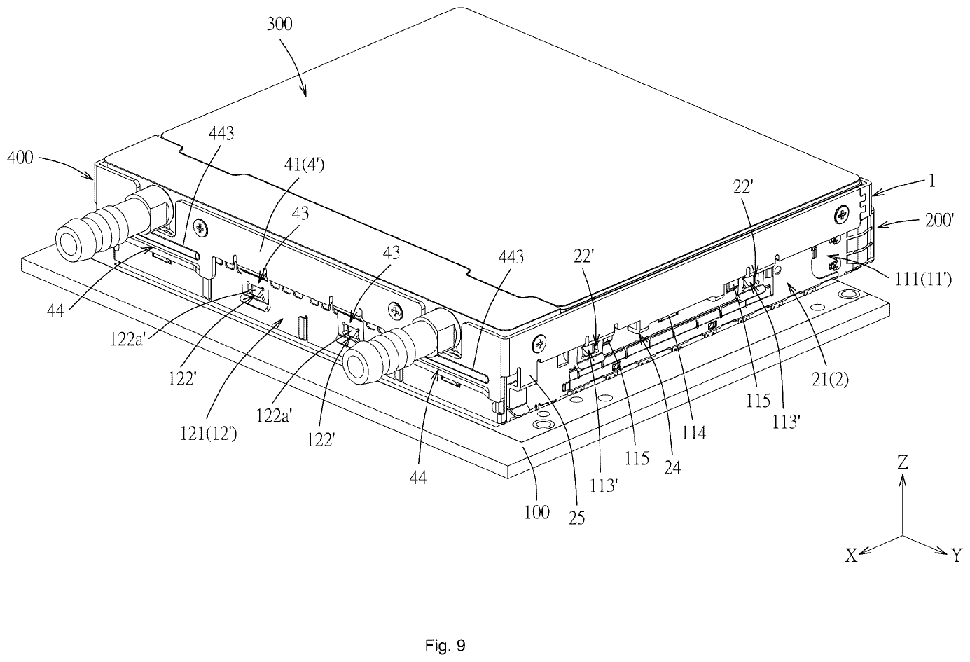

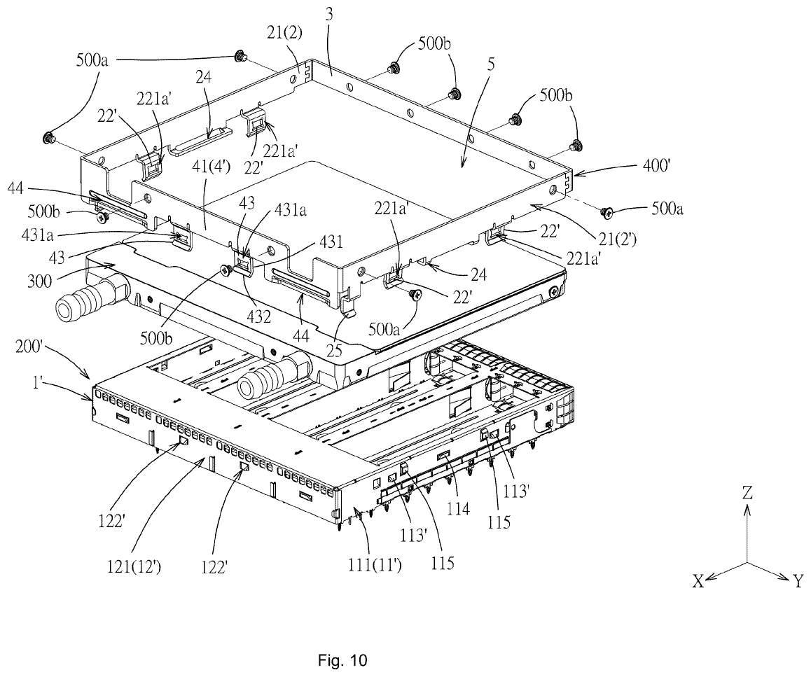

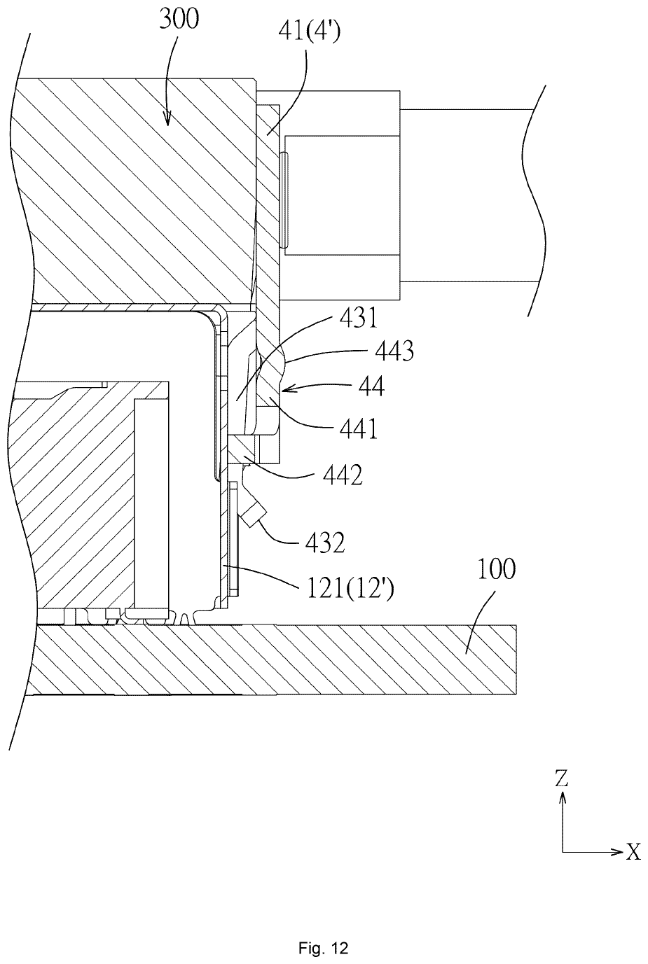

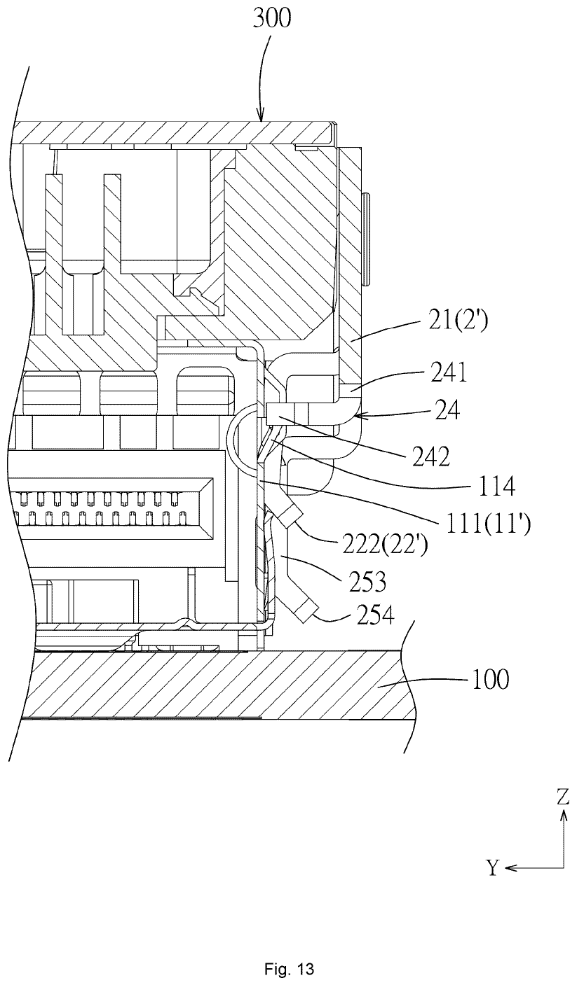

Referring to FIG. 7 to FIG. 14, a second embodiment of the connection device of the present disclosure is illustrated. The connection device is similar to the aforementioned first embodiment, includes a circuit board 100, a connector assembly 200′, a liquid cooling plate 300, a framework 400′ and a plurality of screws. One difference of the connection device from the aforementioned first embodiment lies in that, each side wall 11′ of a metal shell 1′ of the connector assembly 200′ has a side wall main body 111, two side retaining portions 113′ which are provided front and rear, a lower stopping portion 114; and two side stopping portions 115. Each side retaining portion 113′ has a first guiding surface 113a′ which extends outwardly (that is, away from the side wall main body 111) and downwardly. The lower stopping portion 114 is positioned between the two side retaining portions 113′. The two side stopping portions 115 are respectively provided between a front side and a rear side of the lower stopping portion 114 and the adjacent side retaining portions 113′.

Another difference of the connection device from the aforementioned first embodiment lies in that, each side frame 2′ of the framework 400′ has a side frame main body 21, two side latching members 22′ which extend downwardly from a bottom edge of the side frame main body 21 and are arranged front and rear, and a second position-limiting member 24. The side latching members 22′ are capable of being elastically deformed when the side latching members 22′ are subjected to forces respectively, and each have a first latching hole 221a′ which is capable of allowing the corresponding side retaining portion 113′ to pass therein. Each side latching body 221 is formed with the first latching hole 221a′. Each second position-limiting member 24 has an extending portion 241 which extends downwardly, and an abutting portion 242 which extends inwardly from a bottom of the extending portion 241.

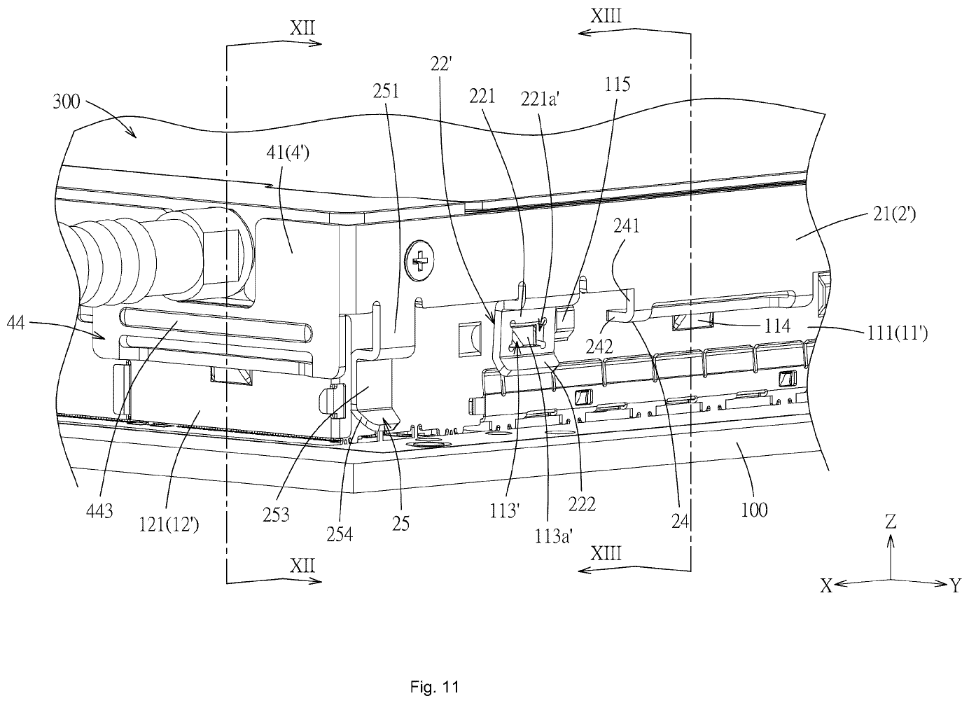

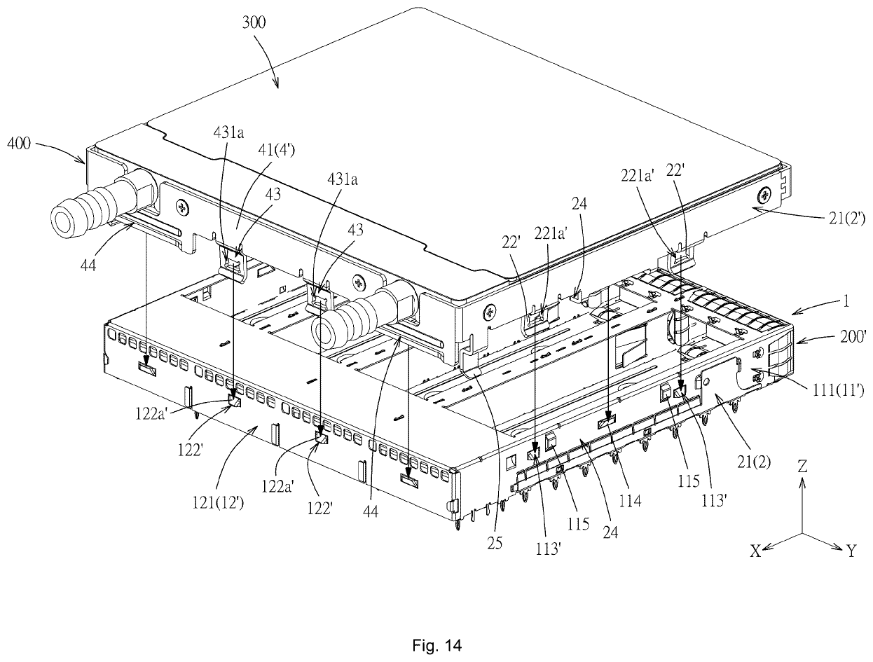

Referring to FIG. 11 to FIG. 14, in a process that the liquid cooling plate 300 is assembled to the connector assembly 200′ by means of the framework 400′, the framework 400′ will be operated to move downwardly as shown by solid arrows in FIG. 14, at this time, the side latching members 22′ are subjected to forces respectively to be elastically deformed respectively along the first guiding surfaces 113a′, the first latching holes 221a′ are capable of being passed therein respectively by the side retaining portions 113′, the side latching members 22′ are respectively limited to moving up, down, front, and rear by the side retaining portions 113′, that is, the side latching members 22′ respectively latch to the side retaining portions 113′, so that the liquid cooling plate 300 is assembled to the connector assembly 200′ by means of the framework 400′, and is engage with the connector assembly 200′, and the liquid cooling plate 300 is limited to displacing relative to the connector assembly 200′ by means of the framework 400′. At the same time, the abutting portions 242 of the second position-limiting members 24 are respectively abutted by the lower stopping portions 114 to be limited to moving downwardly, and bottom edges of inner walls of the first latching holes 221a′ are respectively abutted by bottom surfaces of the side retaining portions 113′ to be limited to moving upwardly, thereby avoid the framework 400′ trembling up and down relative to the connector assembly 200′ after the assembling is completed. Preferably, the second position-limiting members 24 are elastic members. Moreover, in the second embodiment, when the framework 400′ brings the liquid cooling plate 300 to approach the connector assembly 200′ from up to down, the side latching members 22′ will slide downwardly along side edges of the side stopping portions 115 respectively to be respectively limited by the side stopping portions 115, so that the side latching members 22′ cannot move front and rear, but can be guided to be toward the side retaining portions 113′ respectively.

Preferably, each side latching member 22′ has a side latching body 221 and a first latching guide portion 222 which extends downwardly and outwardly (that is, in a direction away from the side frame main body 21) from a bottom of the side latching body 221. When the framework 400′ brings the liquid cooling plate 300 to approach the connector assembly 200′ from up to down, the first latching guide portions 222 are pushed respectively by the side retaining portions 113′ to bring the side latching bodies 221 to be elastically deformed outwardly, which is beneficial for the side latching members 22′ to latch with the side retaining portions 113′ respectively.

Still another difference of the connection device from the aforementioned first embodiment lies in that, a rear wall 12′ of the metal shell 1′ has a rear wall main body 121 and two rear retaining portions 122′ which are provided left and right to the rear wall main body 121. Each rear retaining portion 122′ has a second guiding surface 122a′ which downwardly extends outwardly from an outer surface of the rear wall main body 121 of the rear wall 12 (that is, in a direction away from the rear wall main body 121). And, a rear frame 4′ of the framework 400′ has a rear frame main body 41, two rear latching members 43 which are provided left and right, and two oppressing members 44 which are provided left and right. The rear latching members 43 extend downwardly and are capable of being elastically deformed when the rear latching members 43 are subjected to forces respectively. Each rear latching member 43 has a second latching hole 431a whose front surface and rear surface are penetrated and is capable of allowing the rear retaining portion 122′ to pass therein. The rear latching members 43 are respectively subjected to forces to be elastically deformed respectively along the second guiding surfaces 122a′, so that the second latching holes 431a are capable of being respectively passed therein by the rear retaining portions 122′. The rear latching members 43 are limited to moving up, down, left and right by the rear retaining portions 122′ respectively, that is, the rear latching members 43 respectively latch to the rear retaining portions 122′, so that a rear side of the liquid cooling plate 300 also is assembled to the connector assembly 200′ by means of the framework 400′, and the liquid cooling plate 300 is firmer.

Preferably, each rear latching member 43 further has a rear latching body 431 and a second latching guide portion 432 which extends downwardly and outwardly from a bottom of the rear latching body 431. The rear latching body 431 is formed with the second latching hole 431a. When the framework 400′ brings the liquid cooling plate 300 to approach the connector assembly 200′ from up to down, the second latching guide portions 432 are respectively pushed by the rear retaining portions 122′ to respectively bring the rear latching bodies 431 to be elastically deformed outwardly, which is beneficial for the rear latching members 43 to latch with the rear retaining portions 122′ respectively.

Further, each oppressing member 44 has a plate portion 441 which extends downwardly and is capable of being elastically deformed, a protruding bar 442 which extends from the plate portion 441 toward a direction close to the rear wall 12′, and a protruding rib 443 which extends from the plate portion 441 toward a direction away from the rear wall 12′ and is positioned above the protruding bar 442. When the framework 400′ brings the liquid cooling plate 300 to approach the connector assembly 200′ from up to down, the protruding bars 442 are subjected to a force by the rear wall 12′ to respectively bring the plate portions 441 to be elastically deformed toward the direction away from the rear wall 12′, and first elastic restoring forces which are toward the front are generated, the first elastic restoring forces let the framework 400′ forwardly and tightly lean against the connector assembly 200′, so that the framework 400′ is more firmly assembled to the connector assembly 200′. The protruding rib 443 is used to strengthen a structure of the oppressing member 44 to make the oppressing member 44 not easily deformed.

Preferably, each side frame 2′ further has a guiding member 25. The guiding member 25 has an elastic piece portion 251 which extends downwardly, a pressing portion 253 which downwardly extends from the elastic piece portion 251 close to the side wall 11, and a guiding portion 254 which extends downwardly and outwardly from a bottom of the pressing portion 253. The elastic piece portion 251 is capable of being elastically deformed when the elastic piece portion 251 is subjected to a force. And a length of the guiding member 25 which extends downwardly is larger than a length of the side latching member 22′ which extends downwardly, as such, when the framework 400′ brings the liquid cooling plate 300 to approach the connector assembly 200′ from up to down, the guiding portions 254 will contact the connector assembly 200′ respectively prior to the side latching members 22′, at this time, the guiding portions 254 are respectively pushed by top edges of the side walls 11′ to bring the elastic piece portions 251 to be elastically deformed respectively toward directions which are respectively away from the side walls 11′, and second elastic restoring forces which respectively are inward are generated. The second elastic restoring forces let the pressing portions 253 respectively press against the side walls 11′, thereby avoiding the framework 400′ shaking left and right.

In conclusion, by that the side latching members 22, 22′ respectively latch with the side retaining portions 113, 113′, the liquid cooling plate 300 can be directly assembled to the connector assembly 200, 200′ by means of the framework 400, 400′, the liquid cooling plate 300 and the connector assembly 200, 200′ are compactly engage with each other, which does not increase an area occupying the circuit board 100, and further can save a step of locking the screws, an effect that assembling convenience is promoted is attained. Moreover, by a design of the guiding grooves 231 or the first guiding surfaces 113a, 113a′, an assembling direction of the framework 400 can be guided, an effect that assembling convenience is promoted can be similarly attained, on the other hand, by that the receiving space 5 receives the liquid cooling plate 300, and the framework 400, 400′ is at least fixed to three sides of the liquid cooling plate 300, the liquid cooling plate 300 can be firmly assembled to the framework 400, 400′.

However, the above description is only for the embodiments of the present disclosure, and it is not intended to limit the implementing scope of the present disclosure, and the simple equivalent changes and modifications made according to the claims and the contents of the specification are still included in the scope of the present disclosure.

What is claimed is:

1. A connection device, comprising:
a connector assembly comprising a metal shell, the metal shell having two side walls, each side wall having a protruding portion and a side retaining portion;
a liquid cooling plate whose interior allows a cooling liquid to communicate therein; and
a framework comprising two side frames which are respectively fixed to two sides of the liquid cooling plate, each side frame having a side latching member and a first position-limiting member, the side latching members being capable of being respectively releasable to latch to the side retaining portions, each first position-limiting member having a guiding groove, the guiding grooves being capable of respectively allowing the protruding portions to slide therein,
the first position-limiting members letting the protruding portions respectively slide into the guiding grooves to make the side latching members respectively latch to the side retaining portions, so that the liquid cooling plate and the connector assembly being engaged with each other.

2. The connection device of claim 1, wherein
the two side frames and the liquid cooling plate are screwed by using screws.

3. The connection device of claim 1, wherein
the framework further comprises a front frame whose left side and right side are respectively connected to front sides of the side frames, and a rear frame whose left side and right side are respectively connected to rear sides of the side frames,
the front frame, the rear frame and the two side frames together surround a periphery of the liquid cooling plate.

4. The connection device of claim 1, wherein
an opening of the guiding groove is toward the front;
the framework further comprises a rear frame whose left side and right side are respectively connected to rear sides of the side frames,
the metal shell further has a rear wall which is positioned to a rear side of the metal shell, the rear wall has a rear retaining portion which protrudes rearwardly;
the rear frame has a rear positioning hole which penetrates front and rear, the rear positioning hole is capable of allowing the rear retaining portion to pass therein from the front to the rear.

5. The connection device of claim 1, wherein
an opening of the guiding groove is toward the front;
each side wall has a side wall main body and the side retaining portion which is provided to the side wall main body, each side retaining portion has a first guiding surface which extends outwardly and rearwardly from an outer surface of the side wall main body;
the side latching members are capable of being elastically deformed when the side latching members are respectively subjected to forces, each side latching member has a first latching hole which penetrates a left surface and a right surface of the side latching member and is capable of allowing the side retaining portion to pass therein;
in a process that the first position-limiting members let the protruding portions respectively slide into the guiding grooves, the side latching members are respectively subjected to forces to be elastically deformed respectively along the first guiding surfaces toward directions respectively away from outer surfaces of the side walls, to make the first latching holes be capable of respectively being passed therein by the side retaining portions, so that the liquid cooling plate and the connector assembly are engaged with each other.

6. A connection device, comprising:
a connector assembly comprising a metal shell, the metal shell having two side walls, each side wall having a side retaining portion and a lower stopping portion;
a liquid cooling plate whose interior allows a cooling liquid to communicate therein; and
a framework comprising two side frames which are respectively fixed to two sides of the liquid cooling plate, each side frame having a side latching member and a second position-limiting member, the side latching members being capable of being respectively releasable to latch to the side retaining portions,
by that the side latching members respectively latch to the side retaining portions and the second position-limiting members are stopped respectively by the lower stopping portions, the liquid cooling plate and the connector assembly being engaged with each other.

7. The connection device of claim 6, wherein
each side wall has the two side retaining portions which are provided front and rear;
each side frame has the two side latching members which are provided front and rear.

8. The connection device of claim 6, wherein
each side retaining portion has a first guiding surface which extends outwardly and downwardly,
each side latching member is capable of being elastically deformed when the side latching member is subjected to a force, and has a first latching hole which is capable of allowing the side retaining portion to pass therein, the side latching members are respectively subjected to forces to be elastically deformed respectively along the first guiding surfaces, to make the first latching holes be capable of being respectively passed therein by the side retaining portions, so that the liquid cooling plate and the connector assembly are engaged with each other.

9. The connection device of claim 8, wherein
each side latching member further has a side latching body and a first latching guide portion which extends downwardly and outwardly from a bottom of the side latching body, the side latching body is formed with the first latching hole;
when the framework brings the liquid cooling plate to approach the connector assembly from up to down, the first latching guide portions are pushed respectively by the side retaining portions to bring the side latching bodies to be elastically deformed outwardly.

10. The connection device of claim 6, wherein
when the side latching members respectively latch to the side retaining portions, the second position-limiting members are respectively abutted by the lower stopping portions to be limited to moving downwardly, and the side latching members are respectively abutted by the side retaining portions to be limited to moving upwardly.

11. The connection device of claim 6, wherein
each side wall further has two side stopping portions which are respectively provided between a front side and a rear side of the lower stopping portion and the adjacent side retaining portions;
when the framework brings the liquid cooling plate to approach the connector assembly from up to down, the side latching members are respectively limited by the side stopping portions and cannot move front and rear.

12. The connection device of claim 8, wherein
the metal shell further has a rear wall which is positioned to a rear side of the metal shell, the rear wall has a rear wall main body and a rear retaining portion which is provided to the rear wall main body, the rear retaining portion has a second guiding surface which extends outwardly and downwardly from an outer surface of the rear wall main body;
the framework further comprises a rear frame which is fixed to a rear side of the liquid cooling plate, the rear frame has a rear latching member, the rear latching member extends downwardly and is capable of being elastically deformed when the rear latching member is subjected to a force, the rear latching member has a second latching hole which is capable of allowing the rear retaining portion to pass therein;
when the rear latching member is subjected to a force to be elastically deformed along the second guiding surface, the second latching hole is capable of being passed therein by the rear retaining portion.

13. The connection device of claim 12, wherein
the rear latching member further has a rear latching body and a second latching guide portion which extends downwardly and outwardly from a bottom of the rear latching body, the rear latching body is formed with the second latching hole;
when the framework brings the liquid cooling plate to approach the connector assembly from up to down, the second latching guide portion is pushed by the rear retaining portion to bring the rear latching body to be elastically deformed outwardly.

14. The connection device of claim 12, wherein
the rear frame further has an oppressing member, the oppressing member has a plate portion which extends downwardly and is capable of being elastically deformed, and a protruding bar which extends from the plate portion toward a direction close to the rear wall;
when the framework brings the liquid cooling plate to approach the connector assembly from up to down, the protruding bar is subjected a force applied from the rear wall to bring the plate portion to be elastically deformed toward a direction away from the rear wall, and a first elastic restoring force which is toward the front is generated, the first elastic restoring force lets the framework forwardly and tightly lean against the connector assembly.

15. The connection device of claim 6, wherein
each side frame further has a guiding member, the guiding member has an elastic piece portion which extends downwardly, a pressing portion which downwardly extends from the elastic piece portion close to the side wall, and a guiding portion which extends downwardly and outwardly from a bottom of the pressing portion, the elastic piece portion is capable of being elastically deformed when the elastic piece portion is subjected to a force;
when the framework brings the liquid cooling plate to approach the connector assembly from up to down, the guiding portions are respectively pushed by top edges of the side walls to respectively bring the elastic piece portions to be elastically deformed toward directions respectively away from the side walls, and second elastic restoring forces are generated, the second elastic restoring forces let the pressing portions respectively press against the side walls.

16. The connection device of claim 6, wherein
each side latching member is capable of being elastically deformed when the side latching member is subjected to a force, and has a first latching hole which is capable of allowing the side retaining portion to pass therein, the second position-limiting member has an extending portion which extends downwardly, and an abutting portion which extends inwardly from a bottom of the extending portion,
when the side latching members respectively latch to the side retaining portions, the abutting portions of the second position-limiting members are respectively abutted by the lower stopping portions to be limited to moving downwardly, and bottom edges of inner walls of the first latching holes are respectively abutted by bottom surfaces of the side retaining portions to be limited to moving upwardly.

17. A connection device, comprising:
a connector assembly comprising a metal shell, the metal shell having two side walls, each side wall having a side retaining portion;
a liquid cooling plate whose interior allows a cooling liquid to communicate therein; and
a framework comprising two side frames which are respectively fixed to two sides of the liquid cooling plate, and a rear frame whose left side and right side are respectively connected to the side frames and are fixed to a rear side of the liquid cooling plate, the side frames and the rear frame together defining a receiving space, the receiving space allowing the liquid cooling plate to placed therein, each side frame having a side latching member, the side latching members being capable of being releasable to respectively latch to the side retaining portions, so that the liquid cooling plate and the connector assembly are engaged with each other, and the liquid cooling plate is limited to displacing relative to the connector assembly.

18. The connection device of claim 17, wherein
the framework further comprises a front frame whose left side and right side are respectively connected to the side frames, the front frame and the rear frame respectively fixed to a front side and the rear side of the liquid cooling plate, the front frame, the rear frame and the two side frames together surround a periphery of the liquid cooling plate.
